(19) United States
(12) Patent Application Publication
(10) Pub. No.: US 2016/0233059 A1
(43) Pub. Date: Aug. 11, 2016

(54) METHODS AND SYSTEMS FOR GENERATING PLASMA TO CLEAN OBJECTS

(71) Applicant: IonField Holdings, LLC, Moorestown, NJ (US)

(72) Inventors: Paul F. Hensley, Moorestown, NJ (US); David Gabriel, Philadelphia, PA (US)

(21) Appl. No.: 15/017,317

(22) Filed: Feb. 5, 2016

Related U.S. Application Data
(60) Provisional application No. 62/113,230, filed on Feb. 6, 2015.

(51) Int. Cl. H01J 37/32

(52) U.S. Cl. CPC H01J 37/32348; H01J 2237/335

(57) ABSTRACT

A system to generate plasma to clean at least one object, the apparatus comprising a microplate with an electrode support array comprising a plurality of matched pairs of elongated dielectric barrier members connected to a plurality of electrodes, with said dielectric barrier members of said matched pair being spaced at a pre-determined non-uniform gap, a variable time scale pulsed power source electrically coupled to said electrodes to provide electrical pulses and a plurality of electronic components to control polarity of said electrical pulses, such that said pulses produce electron streamers from opposing elongated dielectric barrier members of said plurality of matched pairs and charge on a surface of said dielectric barrier member is substantially evenly distributed.

### CROSS-REFERENCE TO RELATED APPLICATIONS

This application claims the benefit of U.S. Provisional Patent Application Ser. No. 62/113,230 filed on Feb. 6, 2015, entitled “METHODS AND SYSTEMS FOR GENERATING PLASMA USING PROGRAMMABLE VARIABLE TIME SCALE PULSE POWER SUPPLY”, which is incorporated herein by reference in its entirety.

### BACKGROUND

1. Field of Invention

Embodiments disclosed herein relate, in general, to methods and systems to produce plasma using DC and/or AC high voltage power sources and, more particularly, to methods and systems to generate plasma using programmable variable time scale pulse DC and/or AC high voltage power sources.

2. Description of Related Art

Conventional plasma generating systems include pulsed DC power supplies and AC power supplies. The pulsed DC power supplies in these conventional systems produce regularly timed, short bursts of energy that produce immediate loading and capacitive discharge. The AC power supplies in these conventional systems load the systems during the current increase and produce a short discharge. Both the pulsed DC power supplies and the AC power supplies used in these conventional systems complicate system design and impedance matching.

Some conventional methods and systems have attempted to improve system design and impedance matching using vacuum plasma hardware and plasma deposition hardware. Other attempts to generate plasma have been made in high pressure environments (e.g., atmospheric pressure and near atmospheric pressure). A continuing need exists, however, for better and more efficient plasma generating systems.

Conventional plasma generating systems using AC power supplies produce undesirable amounts of heat to generate atmospheric pressure plasma. These systems continuously drive the current into matched pairs of individual dielectric barrier discharge plates that are angled with respect to each other. Accordingly, a gap distance exists between plates that is not uniform along a length of the plates due to manufacturing tolerances and thermal expansion, or along a z-axis (i.e., a vertical axis height) between the plates due to the plates being angled. Non-uniformity of gap distances between discharge plates alters the shape of spaces that micro-discharges fill within the gaps. The frequency of the AC waveform applied to the discharge plates are, to some degree, determined by the gap distances. For example, one frequency of the AC waveform applied to the discharge plates generate a narrow band (i.e., a narrow region) of plasma more at the bottom of the gap while another frequency may generate plasma more at the top of the gap. In either case, there is less plasma and more heat generated due to concentration of the discharge in a narrow band.

Conventional systems and methods address the non-uniform gap distance using a complicated and inefficient tuning process to identify a frequency to generate the plasma approximately uniformly along the length of the plates within the gap. These conventional systems and methods determine a frequency at an intermediate distance and hope the plasma fills the space where the gap distance increases.

Further, conventional plasma generating systems use a dielectric barrier discharge under atmospheric pressure in air that includes microburst filaments or streamers, which exhibit a memory effect leading to a less uniform plasma. For example, the streamers contact a location of a surface and leave a residual charge on the surface at that location. The next time the streamer is fired in the direction of the surface, the streamer hits the same location.

Thus, there is a need for a device to control power supply of a plasma generating system.

### SUMMARY

Embodiments in accordance with the present invention provide a system to generate plasma to clean at least one object. One system embodiment may include a microplate with an electrode support array comprising a plurality of matched pairs of elongated dielectric barrier members connected to a plurality of electrodes, with dielectric barrier members of each matched pair being spaced at a pre-determined non-uniform gap. Another system embodiment may include an electrode support array configured or shaped to allow insertion of pipette tips at least partially between the electrodes. The systems further include a variable time scale pulsed power source electrically coupled to the plurality of electrodes to provide a plurality of electrical pulses. The systems further include a plurality of electronic components (i.e., a circuit) to control a polarity of a plurality of electrical pulses, wherein the plurality of electrical pulses produce electron streamers from opposing elongated dielectric barrier members of the plurality of matched pairs, and a charge on a surface of the dielectric barrier member is substantially evenly distributed.

Embodiments in accordance with the present invention further provide an apparatus to generate plasma to clean at least one object with a variable time scale pulse power source to generate electrical pulses. The power source includes an input line connected to an AC line. The power source includes an output line coupled to and feeding electrical pulses to a plurality of electrodes and a plurality of matched pairs of elongated dielectric barrier members corresponding to the electrodes. The power source includes a logic board with programmable modules. The power source includes a power board with a plurality of rectifiers, at least one buck regulator, at least one H-Bridge control circuit, a plurality of filters, at least one current sensing circuit and a plurality of electronic components to control polarity of the electrical pulses, such that the electrical pulses produce electron streamers from opposing elongated dielectric barrier members of each of the plurality of matched pairs and charge on a surface of each dielectric barrier member is substantially evenly distributed.

Embodiments in accordance with the present invention further provide a system to generate plasma to clean at least one object. One system embodiment may include a microplate with an electrode support array comprising a plurality of matched pairs of elongated dielectric barrier members connected to a plurality of electrodes, wherein the dielectric barrier members of each matched pair are spaced at a uniform or non-uniform gap and are arranged in a plurality of orderly rows. Another system embodiment may include an electrode support array configured or shaped to allow insertion of pipette tips at least partially between the electrodes. The system includes a variable time scale pulsed power source electrically coupled to electrodes to provide electrical pulses. The system includes a plurality of electronic components to control a polarity of electrical pulses, wherein the electrical pulses produce electron streamers from opposing elongated dielectric barrier members of each of the plurality of matched pairs and charge on a surface of each dielectric barrier member is substantially evenly distributed.

Embodiments of the present invention may provide a number of advantages depending on its particular configuration. It is an object of the present invention to provide a system and method to control a power supply of a plasma generating system. One system embodiment of the present invention may comprise a microplate with an electrode support array of a plurality of matched pairs of elongated dielectric barrier members connected to a plurality of electrodes with dielectric barrier members of each matched pair being spaced at a pre-determined uniform or non-uniform gap. Another system embodiment may include an electrode support array configured or shaped to allow insertion of pipette tips at least partially between the electrodes. The system further comprises a variable time scale pulsed power source includes circuitry corresponding to variable DC power supply, analog to digital conversion, H-Bridge, transformers and microprocessors, that is electrically coupled to the plurality of electrodes to produce electron streamers in each matched pair, wherein the power source controls the electron streamers to reduce or eliminate a memory effect by evening out charge on the surface of the elongated dielectric barrier members. Embodiments provide a discharge pattern that is more uniform than a random pattern that starts plasma generation, providing a more uniform density of plasma and active gases that are created by plasma. The variable time scale pulse power supply provides electrical pulses to the plasma generation system. Various components in electronic circuitry are utilized to control an electrical pulse provided to the dielectric barrier system, such as, to reverse a polarity of a DC pulse that provides electron streamers from opposing sides. In this manner, the DC current may behave as AC current without driving current for the entire waveform.

In accordance with exemplary embodiments of the present invention, systems and methods of controlling plasma generation utilize a control circuitry to provide a more uniform or even charge on a surface of a dielectric barrier. Closed loop control methods are used to identify optimal intervals to change polarity of DC pulses for plasma generation. Discharge patterns are provided that are more uniform than random discharge patterns at the start of the plasma generation, providing a more uniform density of the plasma and the active gases that are created by the plasma. Denser plasma may be developed with less heat. The plasma generation circuitry may sweep through the identified band.

Current systems and methods of the known art use algorithms based on a ramp timing to produce plasma. In contrast, embodiments in accordance with the present disclosure include control circuits that provide for programmable preloading of the dielectric power source. Embodiments utilize a pulsed stepping approach whereby the amplitude and length of the pulse may be changed independently based on the loading characteristics of the circuit and dielectric. For example, embodiments take a certain amount of time to load the system with a pre-discharge voltage (i.e., a voltage on discharge plates that is not high enough to cause an arc or produce plasma), in order to reduce an electrical jolt to the system when plasma is to be produced. Embodiments may load the system with about 500 volts, so that a lesser increase in voltage is needed in order to produce plasma. In this way, embodiments are able to facilitate a longer useful lifetime for the circuit and discharge plates.

In accordance with exemplary embodiments of the present invention, there is provided an apparatus to generate plasma to clean at least one object with a variable time scale pulse power source generating electrical pulses, the power source comprising, an input line connected to an AC or DC line, an output line coupled to and feeding electrical pulses to a plurality of electrodes and a plurality of matched pairs of elongated dielectric barrier members corresponding to the electrodes, a logic board with programmable modules, a power board with rectifiers, at least one buck regulator, at least one H-Bridge control circuit, a plurality of filters, at least one current sensing circuit and a plurality of electronic components to control a polarity of the electrical pulses, such that the pulses produce electron streamers from opposing elongated dielectric barrier members of each plurality of matched pairs and charge on a surface of each dielectric barrier member is substantially evenly distributed.

In accordance with exemplary embodiments of the present invention, systems and methods to generate a pulsed DC, and a Reversible Pulsed DC (RPDC) are provided. The RPDC is pulsed DC that switches direction at a very slow rate relative to the firing frequency. The reversing of the pulsed DC may or may not be alternating. The reversing of the pulsed DC may also include substantially any number of patterns for both power level and frequency.

Embodiments may include: variable frequency high voltage power source for plasma generation; variable duty cycle; variable polarity (dual sided or pulse DC); custom cabling for noise shielding (e.g., fiber optic cabling for control circuits), load coupling and safety; low temperature plasma generation; low frequency plasma generation; closed loop feedback for plasma verification using instrumentation and sensors built into the plasma generation device; protection circuitry (e.g., for arc detection, for leak detection to detect a leak in an enclosure surrounding or sealing at least a portion of the plasma generation apparatus, for short circuit detection, etc.); biasing pre-load at non-plasma generating power setting, using higher power to trigger discharge to improve evenness of plasma and precision of discharge timing; reversing the discharge polarity of DC; non-regular patterned pulse timing and predetermined values for each discharge. Embodiments may also include MOSFETs, IGBTs and similar electrical components.

Load coupling, as disclosed herein, is used with reference to an output filter, before the primary of an output transformer that provides both voltage step up and impedance matching for an output stage of an H bridge circuit.

These and other advantages will be apparent from the present application of the embodiments described herein.

The preceding is a simplified summary to provide an understanding of some embodiments of the present invention. This summary is neither an extensive nor exhaustive overview of the present invention and its various embodiments. The summary presents selected concepts of the embodiments of the present invention in a simplified form as an introduction to the more detailed description presented below. As will be appreciated, other embodiments of the present invention are possible utilizing, alone or in combination, one or more of the features set forth above or described in detail below.

### BRIEF DESCRIPTION OF THE DRAWINGS

The foregoing and other aspects of the embodiments disclosed herein are best understood from the following detailed description when read in connection with the accompanying drawings. For the purpose of illustrating the embodiments disclosed herein, there is shown in the drawings embodiments that are presently preferred, it being understood, however, that the embodiments disclosed herein are not limited to the specific instrumentalities disclosed. Included in the drawings are the following figures:

FIG. 1A is a perspective view of an exemplary plasma generator, according to embodiments disclosed herein;

FIG. 1B is a cross sectional view of the exemplary plasma generator shown in FIG. 1A;

FIG. 1C is a front view of the exemplary plasma generator shown in FIG. 1A;

FIG. 1D is top view of the exemplary plasma generator shown in FIG. 1A;

FIG. 1E is an exploded view of the exemplary plasma generator shown in FIG. 1A;

FIG. 2A is a perspective view of an exemplary electrode support array that may be used according to embodiments disclosed herein;

FIG. 2B is a side view of the exemplary electrode support array shown in FIG. 2A;

FIGS. 2C through FIG. 2F illustrates exemplary electrodes of the electrode support array shown in FIG. 2A and 2B for use with embodiments disclosed herein.

FIGS. 3A through 3C illustrates exemplary electronic circuitry and components that may be used with a plasma generator according to embodiments disclosed herein;

FIG. 4 illustrates exemplary electronic circuitry of a variable DC Power Supply which may be used with a plasma generator according to embodiments disclosed herein;

FIG. 5 illustrates exemplary electronic circuitry of an H bridge connected to the variable DC Power Supply shown in FIG. 4;

FIG. 6 illustrates exemplary transformer circuitry connected to the H bridge circuitry shown in FIGS. 5; and

FIG. 7 illustrates exemplary buck regulator circuitry for use with the variable DC Power Supply shown in FIG. 4.

While embodiments of the present invention are described herein by way of example using several illustrative drawings, those skilled in the art will recognize the present invention is not limited to the embodiments or drawings described. It should be understood the drawings and the detailed description thereto are not intended to limit the present invention to the particular form disclosed, but to the contrary, the present invention is to cover all modification, equivalents and alternatives falling within the spirit and scope of embodiments of the present invention as defined by the appended claims.

The headings used herein are for organizational purposes only and are not meant to be used to limit the scope of the description or the claims. As used throughout this application, the word “may” is used in a permissive sense (i.e., meaning having the potential to), rather than the mandatory sense (i.e., meaning must). Similarly, the words “include”, “including”, and “includes” mean including but not limited to. To facilitate understanding, like reference numerals have been used, where possible, to designate like elements common to the figures

### DETAILED DESCRIPTION

Embodiments of the present invention will be described below in conjunction with exemplary laboratory equipment. Embodiments of the present invention are not limited to particular types of laboratory equipment. Those skilled in the art will recognize the disclosed techniques may be used in substantially any laboratory equipment in which it is desirable to detect and clean contaminants.

The phrases “at least one”, “one or more”, and “and/or” are open-ended expressions that are both conjunctive and disjunctive in operation. For example, each of the expressions “at least one of A, B and C”, “at least one of A, B, or C”, “one or more of A, B, and C”, “one or more of A, B, or C” and “A, B, and/or C” means A alone, B alone, C alone, A and B together, A and C together, B and C together, or A, B and C together.

The term “a” or “an” entity refers to one or more of that entity. As such, the terms “a” (or “an”), “one or more” and “at least one” may be used interchangeably herein. The terms “comprising”, “including”, and “having” also may be used interchangeably.

The term “automatic” and variations thereof, as used herein, refers to substantially any process or operation done without material human input when the process or operation is performed. However, a process or operation may be automatic, even though performance of the process or operation uses material or immaterial human input, if the input is received before performance of the process or operation. Human input is deemed to be material if such input influences how the process or operation will be performed. Human input that consents to the performance of the process or operation is not deemed to be “material”.

As used herein, the term “module” refers generally to a logical sequence or association of steps, processes or components. For example, a software module may comprise a set of associated routines or subroutines within a computer program. Alternatively, a module may comprise a substantially self-contained hardware device. A module may also comprise a logical set of processes irrespective of any software or hardware implementation.

A module that performs a function also may be referred to as being configured to perform the function, e.g., a data module that receives data also may be described as being configured to receive data. Configuration to perform a function may include, for example: providing and executing computer code in a processor that performs the function; providing provisionable configuration parameters that control, limit, enable or disable capabilities of the module (e.g., setting a flag, setting permissions, setting threshold levels used at decision points, etc.); providing a physical connection, such as a jumper to select an option, or to enable/disable an option; attaching a physical communication link; enabling a wireless communication link; providing electrical circuitry that is designed to perform the function without use of a processor, such as by use of discrete components and/or non-CPU integrated circuits; energizing a circuit that performs the function (e.g., providing power to a transceiver circuit in order to receive data); and so forth.

The terms “determine”, “calculate” and “compute,” and variations thereof, as used herein, are used interchangeably and include substantially any type of methodology, process, mathematical operation or technique.

Plasma is a medium with unbound charged and neutral species. Plasma is generated by either thermal or non-thermal discharges such that energy in the form of electrical field or an electromagnetic field or heat of sufficient intensity is applied to a volume of gas at either atmospheric pressure or near atmospheric pressure or low pressure. A plasma discharge is produced when an electric field of sufficient intensity is applied to a volume of gas. Free electrons are then subsequently accelerated to sufficient energies to produce electron-ion pairs through inelastic collisions. As the density of electrons increase, further inelastic electron atom/molecule collisions will result in the production of further charged carriers and a variety of other species. The species may include excited and metastable states of atoms and molecules, photons, free radicals, molecular fragments, and monomers. The plasma species are chemically active and/or can physically modify the surface of materials and may therefore serve to form new chemical compounds and/or modify existing compounds. For example, the plasma species can modify existing compounds through ionization, dissociation, oxidation, reduction, attachment, and recombination.

A non-thermal, or non-equilibrium, plasma is one in which the temperature of the plasma electrons is higher than the temperature of the ionic and neutral species. Within atmospheric pressure, non-thermal plasma, there is typically an abundance of energetic and reactive particles (i.e., species), such as ultraviolet photons, excited and/or metastable atoms and molecules, atomic and molecular ions, and free radicals. For example, within air plasma, there are excited, metastable, and ionic species of N₂, N, O₂, O, free radicals such as OH, HO₂, NO, O, and O₃, and ultraviolet photons ranging in wavelengths from 200 to 400 nanometers resulting from N₂, NO, and OH emissions. In addition to the energetic (fast) plasma electrons, embodiments of the present invention harness and use these “other” particles to clean and surface condition portions of liquid handling devices, such as probes, and the like.

Dielectric Barrier Discharge (DBD) is a non-thermal discharge generated by the application of high voltages across small gaps between two electrodes wherein the gap is filled by a dielectric barrier. Applications of DBD may include, but are not restricted to, cleaning processes wherein contaminants from surfaces are removed by the breakdown of organic bonds or physical ablation using plasma generated. Surfaces may be cleaned without affecting the bulk properties of the surface material.

Other functions of plasma cleaning include sterilization and removal of microbial entities on the surface of a substrate used in, for example, biomedical applications. Plasma discharge cleaning devices used in biomedical applications (e.g., lonfield's TipCharger™) typically expose a substrate to be cleaned for a short period of time in the scale of seconds causing disassociation of molecules and/or atoms of the material that is the contaminant present inside or on the surface of the substrate.

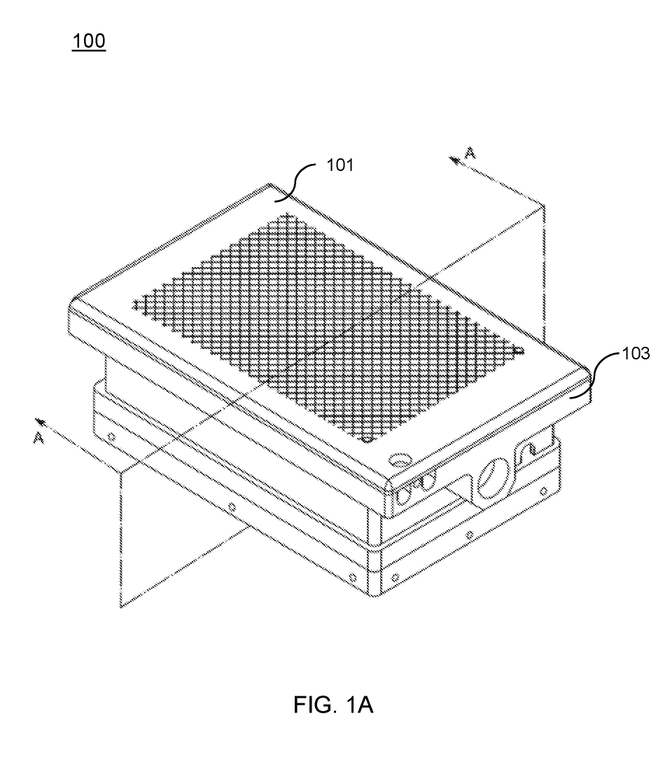

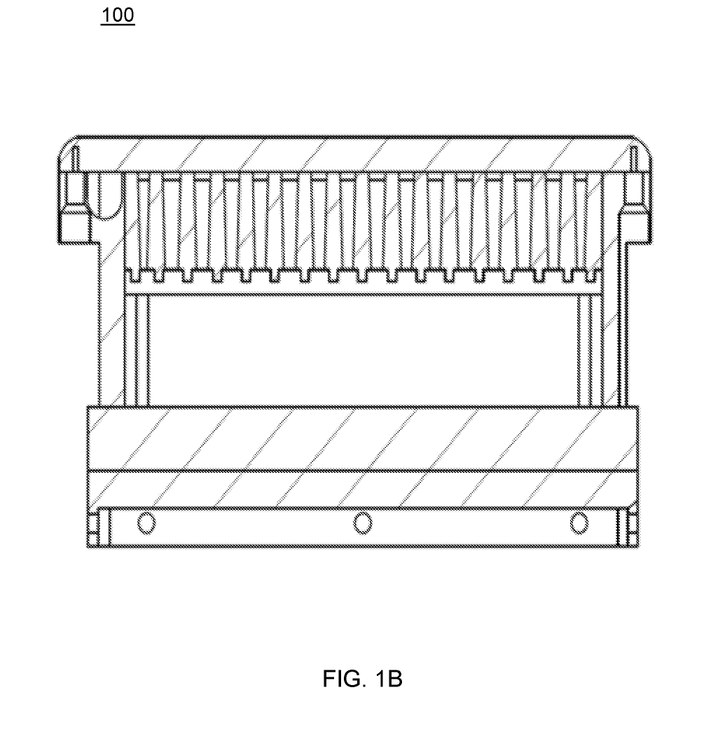

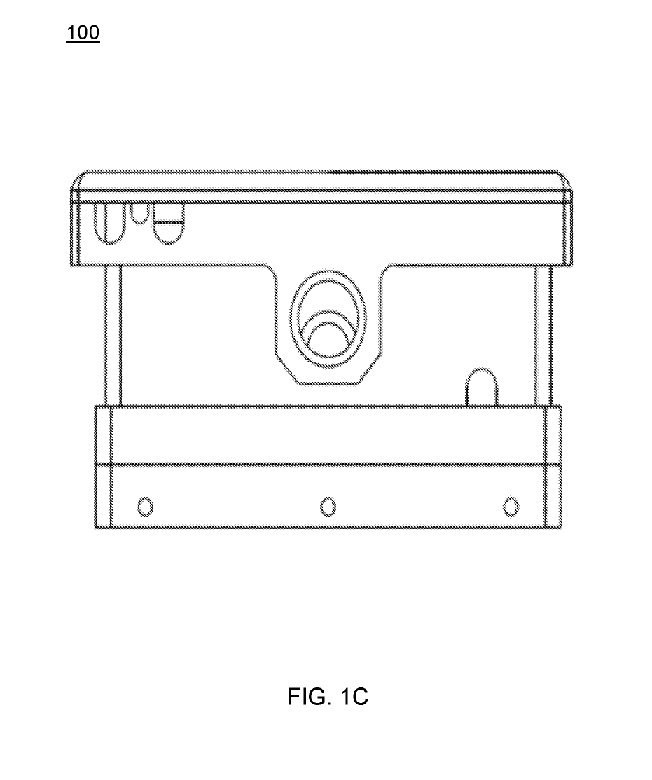

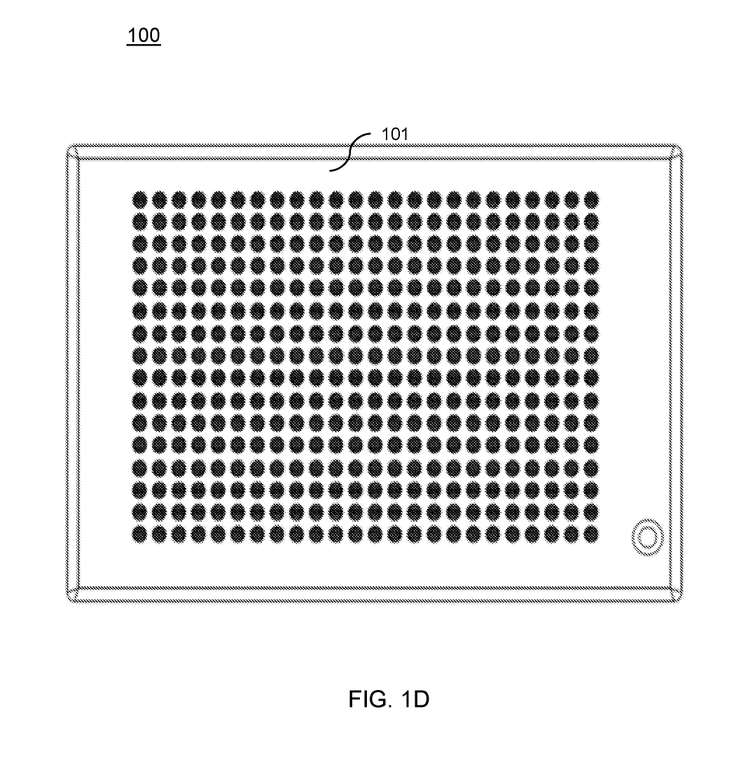

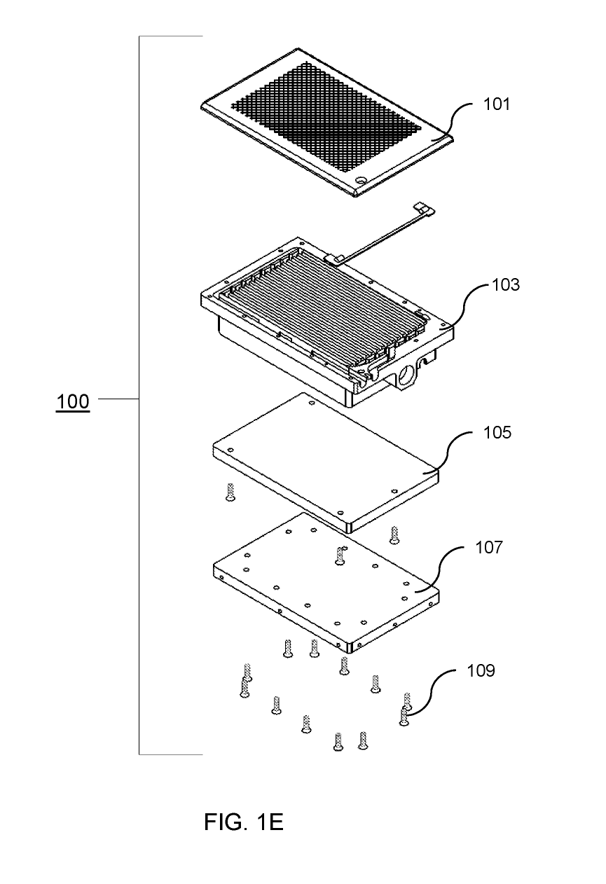

Referring to FIG. 1A, a non-thermal atmospheric pressure plasma discharge cleaning system 100 to generate plasma to clean a substrate 101 is disclosed. Substrate 101 is an object to be cleaned or treated with device 100. The substrate may be used in clinical, industrial, and/or scientific laboratories in some embodiments of the present invention. The substrate may be, but is not restricted to, a sample holding device, a sample handling device, a fluid holding device, a fluid handling device, and the like. The fluid handling device may include, but is not restricted to, a probe, a dropper, and the like. The fluid holding device may include, but is not restricted to, a microplate, a test tube, a microtube, and the like. The microplate is usually a small, plastic reaction vessel. The microplate has a tray covered with wells that are arranged in orderly rows. These wells are used to conduct separate chemical reactions during a fluid testing step. Microplates are ideal for high-throughput screening and research. They allow miniaturization of assays and are suitable for many applications, including, but are not restricted to, drug testing, genetic study, and combinatorial chemistry. In accordance with an embodiment of the present invention, substrate 101 is a microplate.

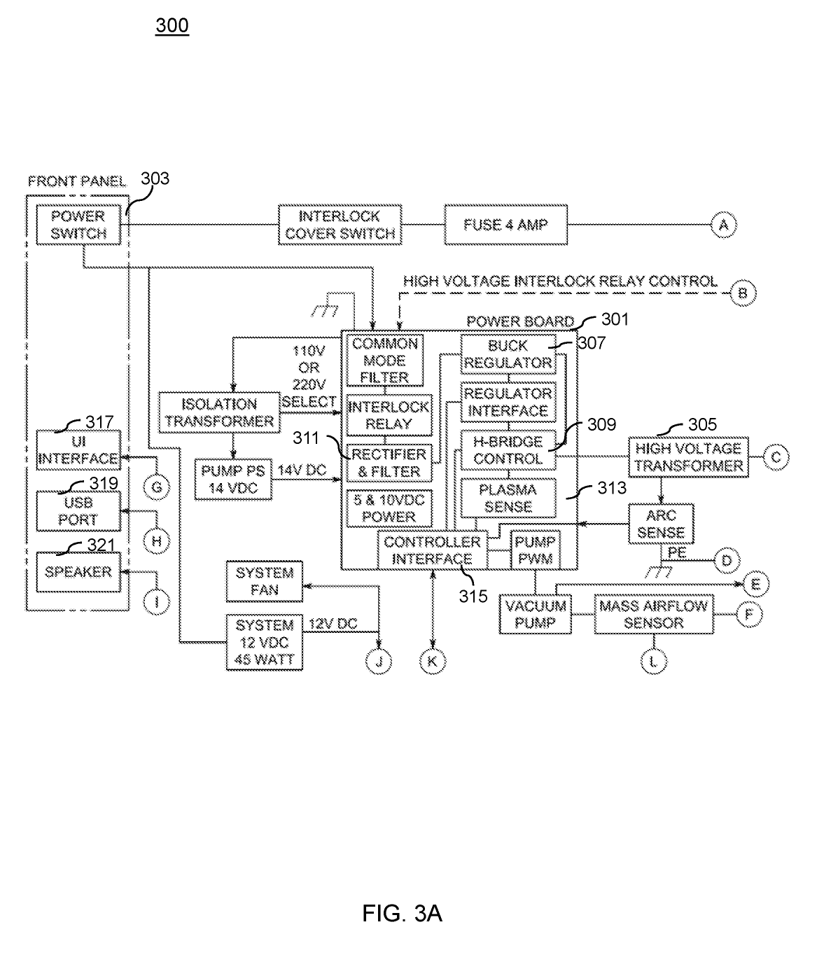

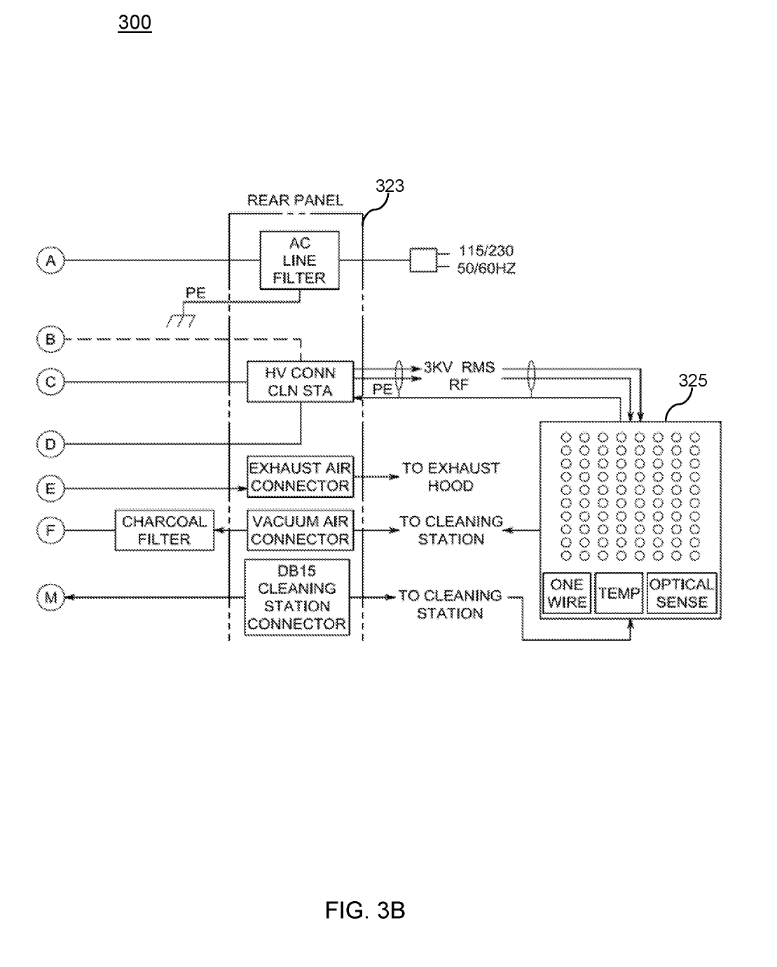

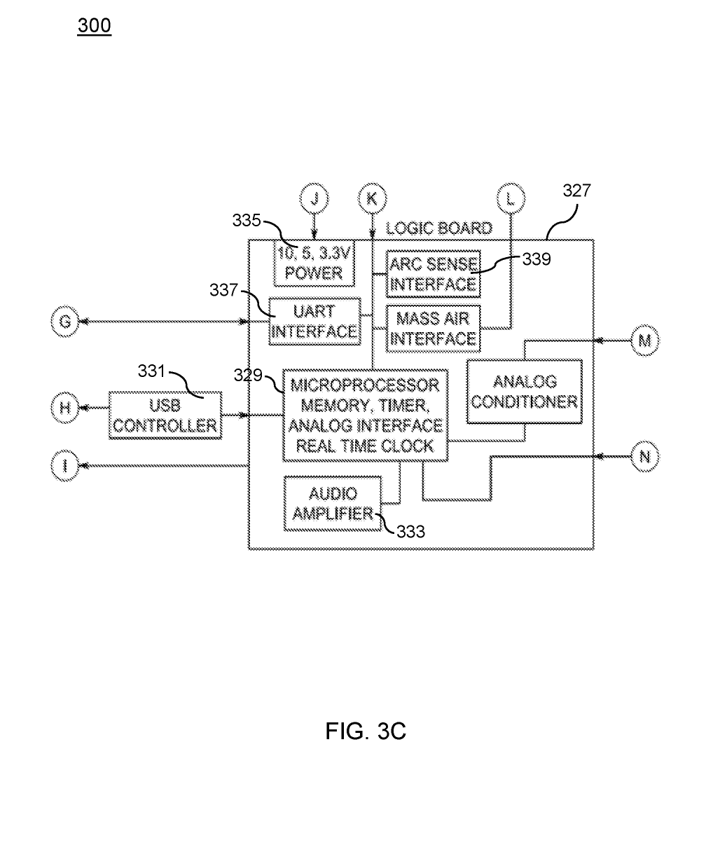

In operation, substrate 101 is placed in, for example, a deck mounted wash station (not shown). In an automated fluid handling instrumentation, the probe tips of the fluid handling device would need cleaning after the performing of an assay test. A set of automated commands initiate and control the probes to be introduced to substrate 101 in such a way that the probe tips are positioned between matched pairs of a plurality of elongated dielectric barrier members fixed on a plasma generation apparatus 103. Alternatively, the positioning of the microplate is done manually. In order to implement the cleaning, a Dielectric Barrier Discharge (DBD) of plasma is formed between the elongated dielectric barrier members and the probes upon the initiation of a variable (i.e., controllable) time scale pulse power source thereby removing contaminants in the probes. The variable time scale pulse power source is described in subsequent paragraphs in the present invention in conjunction with FIGS. 3A, 3B, 3C, 4, 5, 6 and 7.

FIG. 1B is a cross-sectional side view AA of device 100 as marked in FIG. 1A. FIG. 1C is a front view of system 100. FIG. 1D is a top view illustrating substrate 101 as a microplate with multiple wells. FIG. 1E is an exploded view of system 100 shown in FIG. 1A. As shown in FIG. 1E, system 100 includes a substrate 101, a plasma generation apparatus 103 fixed with matched pairs of elongated dielectric barrier members on a planar or non-planar surface 105. Plasma generation apparatus 103 is connected to various programmable modules implementing automated commands and a variable time scale pulsed power source. System 100 is supported on a base 107. Plasma generation apparatus 103, planar or non-planar surface 105 are appended to base 107 and to each other by a number of screws 109. Alternatively, screws 109 may be other types of fasteners that hold together at least portions of system 100. In accordance with different embodiments of the present invention, substrate 101 may be detached or attached pursuant to a set of automated commands generated by programmable modules of system 100.

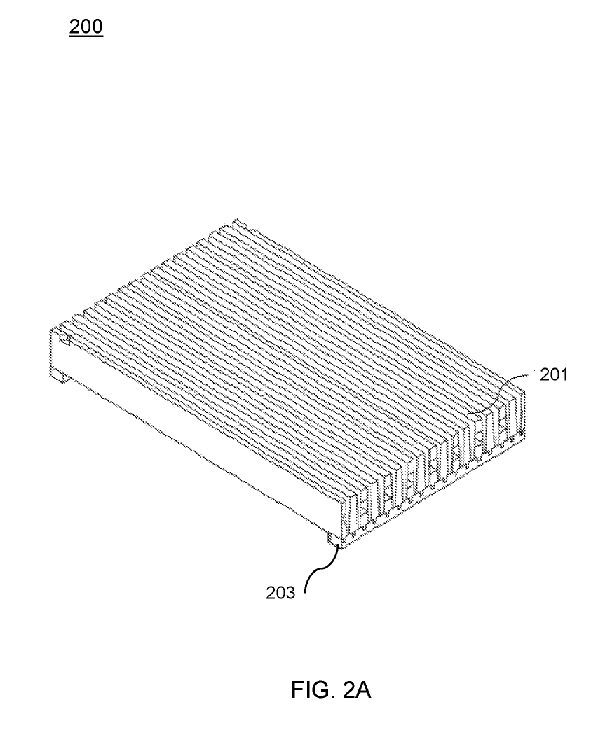

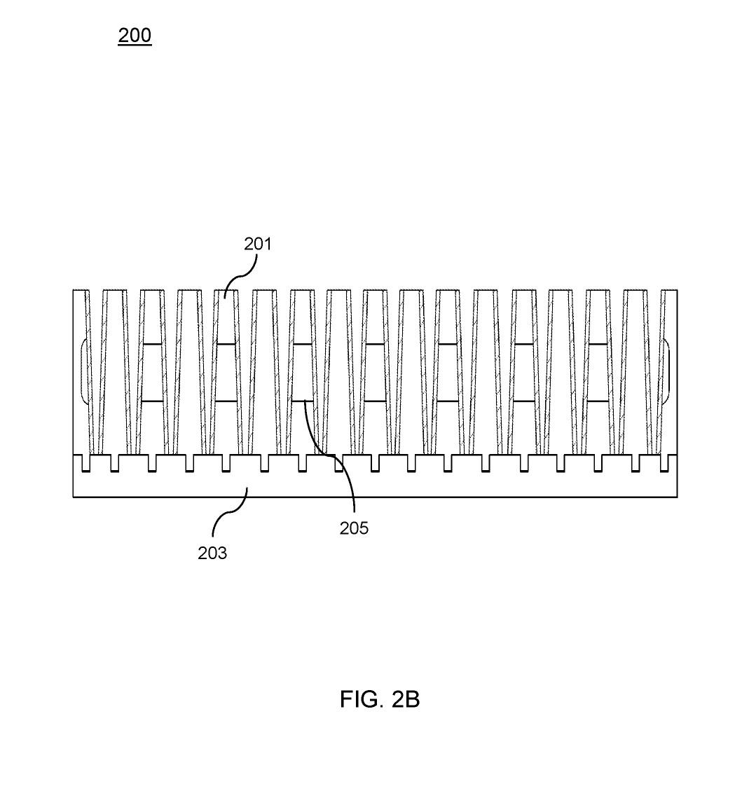

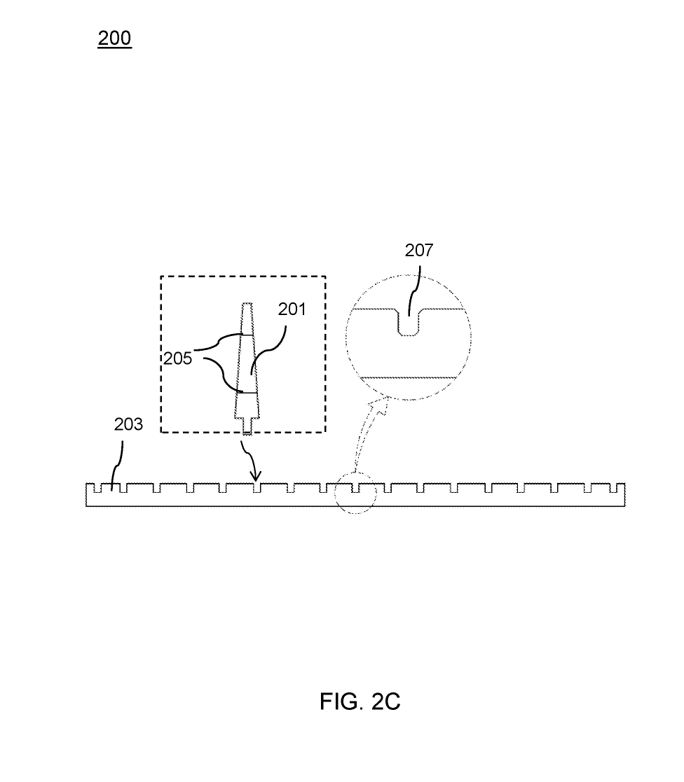

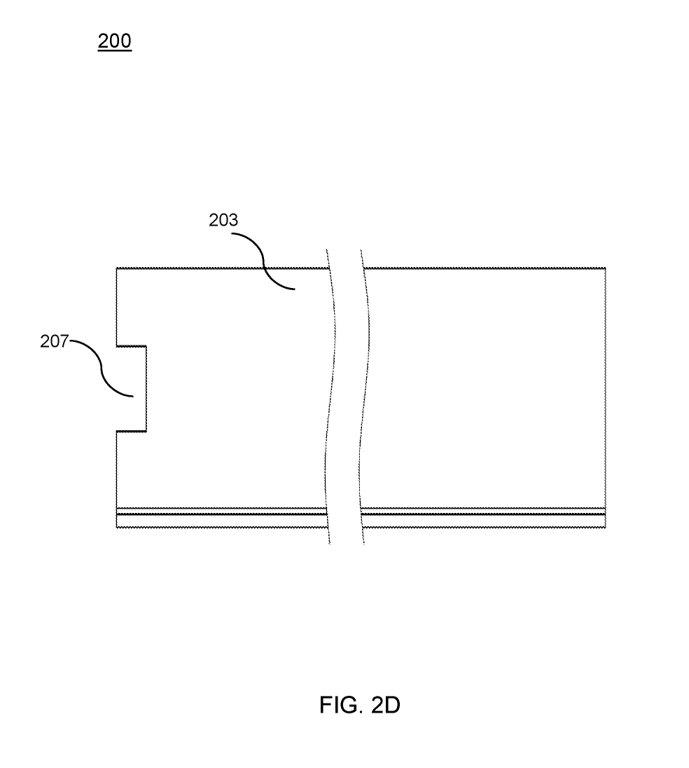

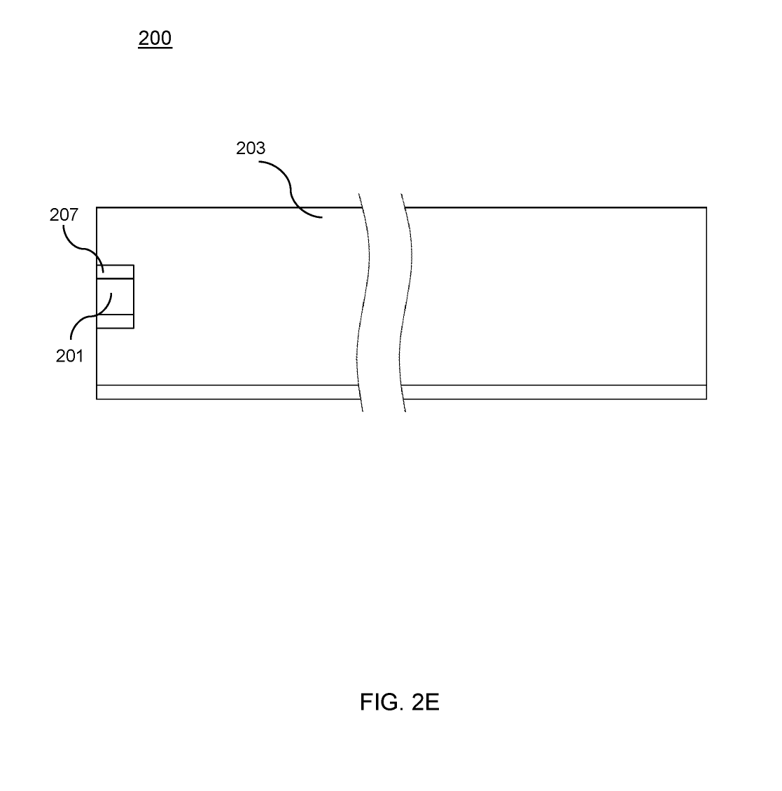

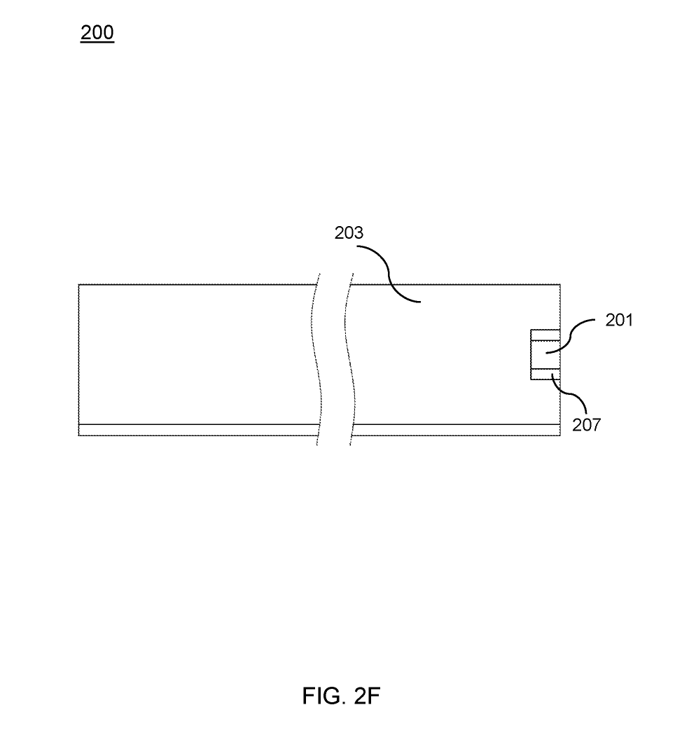

FIG. 2A illustrates an exemplary electrode support array 200, which is part of plasma generation apparatus 103, in accordance with an embodiment of the present invention. Electrode support array 200 includes multiple mutually exclusive elongated dielectric barrier discharge members 201 that are arranged as matched pairs in rows on a support structure 203 with grooves. The size, shape and number of members 201 shown in FIG. 2A is exemplary. Embodiments may include substantially any number of discharge plates having sizes, shapes that are the same or different than those shown in FIG. 2A. Elongated dielectric barrier members 201 are spaced at a pre-determined gap. The gap may be uniform or non-uniform along a length, depending on practical considerations of manufacturing. Each dielectric barrier member 201 includes an inner electrode extending within, and substantially along the length of, respective elongated dielectric barrier members. The electrodes are electrically coupled to a variable time scale pulsed power source.

In operation, embodiments in accordance with the present disclosure reflect a standing wave off surfaces of the electrode. Both plasma and heat are generated, and the system is tuned in order to maximize an amount of generated plasma. Tuning may involve adjustment of the frequency of an input AC signal. Because the input energy is constant, the plasma energy and heat energy are inversely proportional. The generated heat energy is easier to measure, so the plasma energy can be increased or maximized by reducing or minimizing an amount of detected heat energy. Accordingly, embodiments measure the heat formation, and tune the system to a frequency that produces a least amount of heat.

FIG. 2B is a side view of the exemplary electrode support array 200 shown in FIG. 2A. FIG. 2B depicts individual members 201 as being angled with respect to each other, forming alternating A-shaped and V-shaped portions. The angle facilitates insertion of, and cleaning of, an object of matching physical shape that needs cleaning (e.g., a pipette tip, a microwell, etc.). Accordingly, a pre-determined gap distance exists between the plates, the former being uniform or non-uniform between the plates, along a length of the plates and along a z-axis height. In some embodiments, the individual plates of each matched pair of plates may be angled about 3 degrees from each other. However, embodiments disclosed herein may include other angles. For example, if a pin tool is to be cleaned, the pin tool having a rod shape of about 0.475 millimeters (mm) in diameter, then parallel plates (i.e., angle of 0 degrees) may be used.

Members 201 with corresponding electrodes may also include conducting wires 205 electrically coupling the electrodes to a variable time scale pulse power source. Members 201 may be plates that may be tubular, circular, square, rectangular, oval, polygonal, triangular, trapezoidal, rhombus and irregular in shape. Further, members 201 also may be arranged on a non-planar surface. In an exemplary embodiment of the present invention, members 201 may be made of substantially any type of material capable of providing a surface for a dielectric barrier discharge of atmospheric pressure plasma. Dielectric barrier material in this embodiment of the present invention includes, but is not limited to, an air gap, a gap filled with other gaseous material, a non-gaseous material such as ceramic, glass, plastic, polymer epoxy, or a composite of one or more such materials, such as fiberglass or a ceramic filled resin. The inner electrode may include substantially any dielectric material, including metals, alloys and conductive compounds. In one embodiment, a ceramic dielectric barrier is alumina or aluminum nitride. In another embodiment, a ceramic dielectric barrier is a machinable glass ceramic. In yet another embodiment of the present invention, a glass dielectric barrier is a borosilicate glass. In still another embodiment, a glass dielectric barrier is quartz. In an embodiment of the present invention, a plastic dielectric barrier is polymethyl methacrylate. In yet another embodiment of the present invention, a plastic dielectric barrier is polycarbonate. In yet another embodiment, a plastic dielectric barrier is a fluoropolymer. In another embodiment, a plastic dielectric barrier is a polyimide film (e.g., KAPTON™). Dielectric barrier materials useful in the present invention typically have dielectric constants ranging between 2 and 30. For example, in one embodiment that uses a polyimide film plastic such as KAPTON, at 50% relative humidity, with a dielectric strength of 7700 Volts/mil, the film would have a dielectric constant of about 3.5.

FIG. 2C is an exemplary embodiment of support structure 203 with grooves of electrode support array 200 and the side view of elongated dielectric barrier discharge member 201 with wires 205 coupled to a variable time scale pulse power source that may be fitted into one of groove 207 of support structure 203. The walls of member 201 being angled results in non-uniform gaps between members 201 of a matched pair.

FIG. 2D is an exemplary embodiment of support structure 203 with a single groove or well viewed sideways. FIG. 2E illustrates a side view of support structure 201 with a single groove or well 207 and fitted with barrier member 201 shown partially and fitted into groove or well 207. FIG. 2F illustrates a side view of support structure 203 fitted with a partially shown barrier discharge member 201, that is opposite to the side view shown in FIG. 2E.

According to an embodiment of the present invention, a variable time scale pulse power source, that is part of apparatus 103, feeds the elongated dielectric barrier discharge members 201 with a plasma discharge. A main alternating current (AC) supply is connected to apparatus 103 and the variable time scale pulse power source provides a power rectifier that is used to convert the AC voltage signal to a direct current (DC) voltage. In order to generate a pulsed DC signal, the DC signal needs to be driven through a bridge circuit comprising of switching transistors. According to an embodiment of the present invention, Insulated Gate Bipolar Transistors (IGBT) are used for the function of switching. For the operation of high voltage signals, the bridge circuit is preferably fed current from a buck regulator, the buck regulator succeeding the power rectifier stage in the variable time scale pulse power source. The buck regulator may be regulated using monitoring circuitry. Monitoring circuitry, according to various embodiments of the present invention, is used with reference to processing of control voltages, detecting and halting operation in the event of abnormal conditions including inrush current sensing, arc/leak detection (e.g., from the output transformer), short circuit detection, malfunctioning auxiliary power supplies and system overheating. Such circuits are coupled to microprocessor circuits. Transformer circuitry is used for isolation of system 100 and apparatus 103 from the main AC supply. According to another embodiment of the present invention, transformer circuitry is used to keep the various components of the bridge circuit from being coupled to the resultant plasma discharge. In accordance with another embodiment of the present invention, the bridge circuit is driven by a microprocessor such that parameters like the duty cycle and/or pulse width of the DC pulse may be controlled. Duty cycle is related to the spectral content of the driving signal. Duty cycle is used with reference to the type of power waveform driving the plasma and refers to the percentage of the time during which the power source is conducting to a load, the load including a plasma discharge.

FIGS. 3A through 3C are diagrams illustrating different sections of exemplary electronic circuitry and components that may be used with a variable time scale pulse power source according to an embodiment of the present invention.

Referring to FIG. 3A, a section of a complete circuit schematic 300 driving plasma generator apparatus 103 is depicted. There is provided a power board 301 having an exemplary circuitry of a buck regulator 307, a variable DC power supply with a rectifier and filters 311 and buck regulator 307, H Bridge circuitry 309, a protection circuitry with plasma surge and/or arc sensitive circuit components. The protection circuitry is used with reference to a system of security interlocks, which prevent the machine from being run while the case is open and/or the load is disconnected. The output from H Bridge circuitry 309 is stepped up by using a high voltage transformer 305 and then fed to a device 325 as depicted in FIG. 3B. In some embodiments, the output voltage may be about +/−5,000 volts AC. In other embodiments, the output voltage may be about +/−7,000 volts AC. A logic board 321 is linked to power board 301 through a current sensing feedback circuitry and controller interface circuitry 315.

FIG. 3A further illustrates ports on a front panel 303 of apparatus 103. Front panel 303 comprises a power switch and various ports concerning a User Interface 317 (e.g., a display unit), Universal Serial Bus (USB) port 319, a speaker port 321 etc. which are operated by a logic board 327 depicted in FIG. 3C. In accordance with an embodiment of the present invention, system 100 is connected externally to input and/or output devices such as the display unit for the purpose of providing a user interface or graphical user interface aiding in human-device interaction. Speaker port 321 may be used for an auxiliary connection to an audio device (e.g., a speaker) that can generate sounds at a critical event.

Referring to FIG. 3B, in accordance with an embodiment of the present invention, a rear panel 323 with ports connecting to a non-thermal atmospheric pressure plasma discharge cleaning device 325, device 325 being the same in construction and working as system 100 shown in FIG. 1A.

FIG. 3C illustrates an exemplary embodiment of a logic board 327, including a microprocessor unit 329, an audio amplifier 333, arc sense interface controller 335, a Universal Asynchronous Receiver/Transmitter (UART) interface port 337 and a USB controller 331, all of which connect to ports in front panel 303 and power board 301. Modules of logic board 327 monitor and facilitate control of plasma generation and automated positioning of objects to be cleaned. Logic board also reports critical and/or hazardous events.

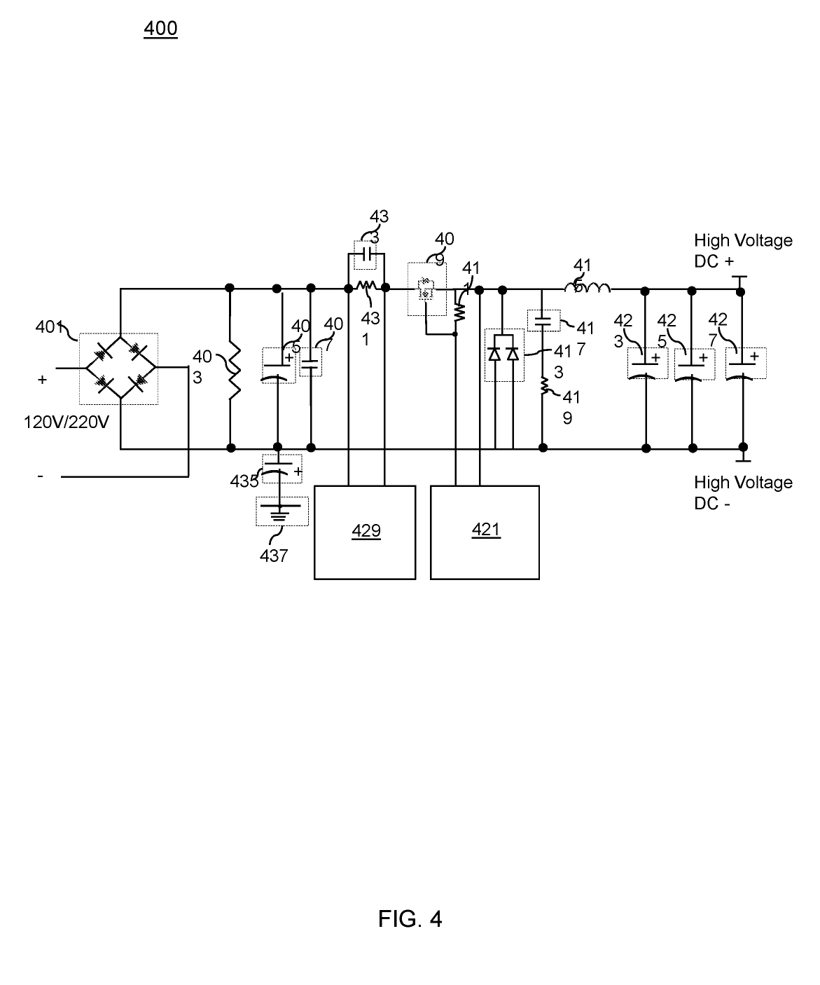

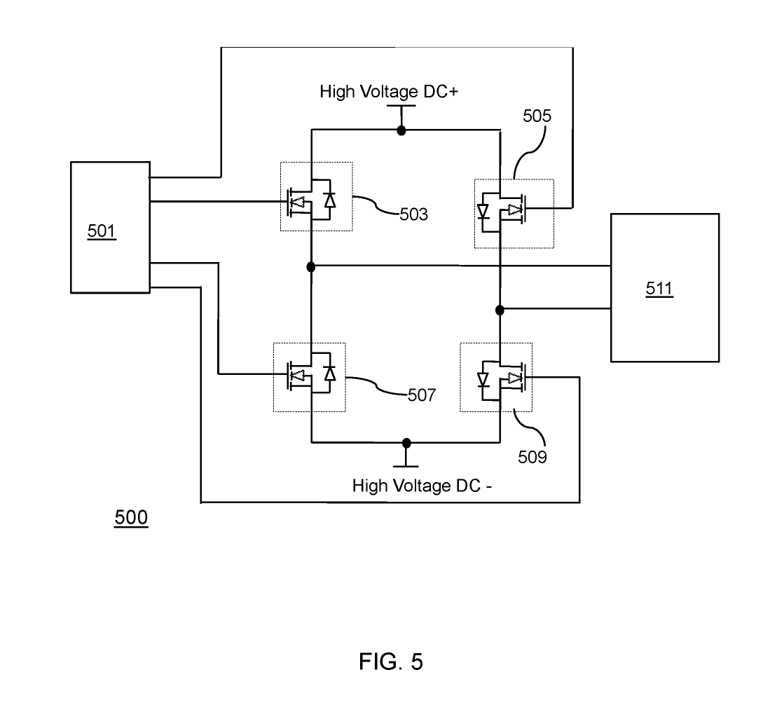

FIG. 4 illustrates an exemplary electronic circuit for a variable DC Power Supply 400, which is a part of the variable time scale pulse power source used with apparatus 103, in accordance with an embodiment of the present invention. As shown in FIG. 4, variable DC Power Supply 400 operates with a line voltage of 120V or 220V, a full-wave bridge rectifier 401, an output filter that includes a resistor 403, parallel capacitors 405 and 407 to reduce ripples. Rectifier 401 rectifies DC voltage received into a conventional buck regulator including components such as, but is not restricted to, a zener shunt diode and a transistor 409, a resistor 411, a pair of zener shunt diodes 413, an inductor 415, a capacitor 417 and a resistor 419. The buck regulator includes a buck regulator controller 421 and is used to control the variable high voltage DC. The output of the buck regulator is then fed through an output filter comprising capacitors 423, 425 and 427. This variable high voltage DC is then fed into an H Bridge full wave converter module 501 as shown in FIG. 5.

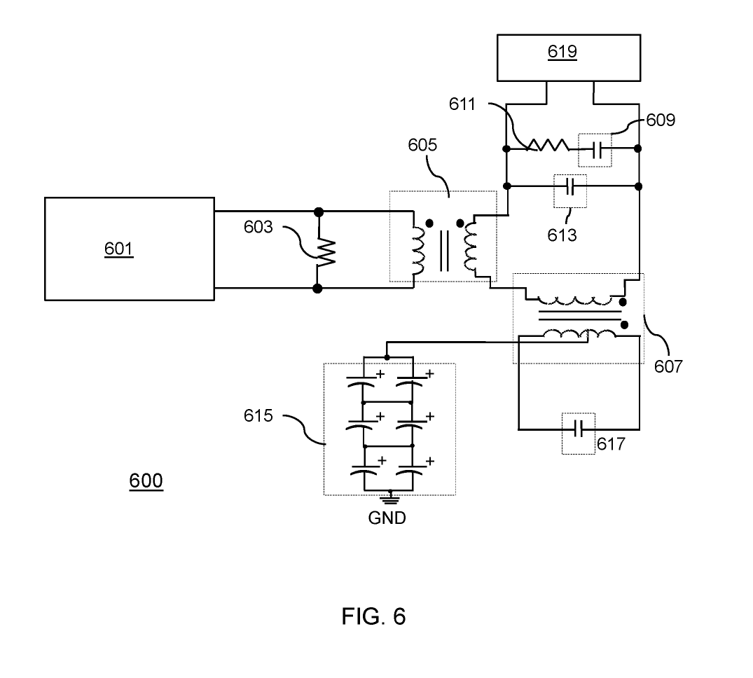

Variable DC Power Supply 400 also includes a current sensing feedback circuitry 429. A voltage across resistor 433 is relative to current drawn by variable DC power supply 400. This voltage is applied to an analog to digital converter 601 of a digital logic board shown in FIG. 6, the working of which is explained in more detail in succeeding paragraphs, to monitor the current drawn from the power supply. Capacitor 431 acts as a low pass filter to monitor this signal.

In the present disclosure, a variable and controllable polarity is used with reference to systems that generate a pulse DC waveform for plasma generation and which may reverse its polarity to generate an inverted version of the same pulse DC waveform. This system may alternate among predetermined configurations with respect to either polarity.

FIG. 5 is a diagram illustrating exemplary electronic circuitry of an H Bridge 500 connected to variable DC Power Supply 400 shown in FIG. 4. H Bridge 500 may enable a voltage to be applied across a load in either direction. As shown in FIG. 5, H Bridge 500 includes a controller 501 along with transistors 503, 505, 507 and 509. According to an embodiment of the present invention, the transistors are IGBTs. An embodiment of the present invention uses output waveforms that alternate between conducting through transistors 503 and 509 simultaneously and then switching to transistors 505 and 507 simultaneously. Each alternating waveform represents one polarity of the waveform. Exemplary embodiments of the present invention use a pulsed DC configuration, which includes successive pulses from the same set of diagonally opposite transistors. Firing may begin with transistors 503 and 509, switching them on and off for a number of cycles and then alternating between 505 and 507 repeatedly for a number of cycles. The output is fed to a transformer circuitry 511. Transformer circuitry 511 isolates the bridge circuit from the plasma discharge generated.

FIG. 6 is a diagram illustrating an exemplary transformer circuitry 600 connected to H bridge circuitry 500 shown in FIG. 5. The Analog to Digital Converter (ADC) 601 is connected to a circuitry associated with microprocessors, Universal Serial Bus ports and other interface ports facilitating programmable modules. The supply to ADC 601 is given by a current sensing feedback element 603. The output of a H Bridge full wave converter module 619 is fed into output transformer circuitry 605 and 607 after passing through a filter including a resistor 611 and a capacitor 609 in series, both shunted with a capacitor 613 before transformer circuitry 605 and 607. An output from transformer 607 is fed to multiple electrodes 617 located on electrode support array 200 shown in FIG. 2A and 2B. A grounding terminal 615 is also provided. Analog to digital converter 601 further feeds into circuitry corresponding to the microprocessor circuitry on logic board 311 shown in FIG. 3C.

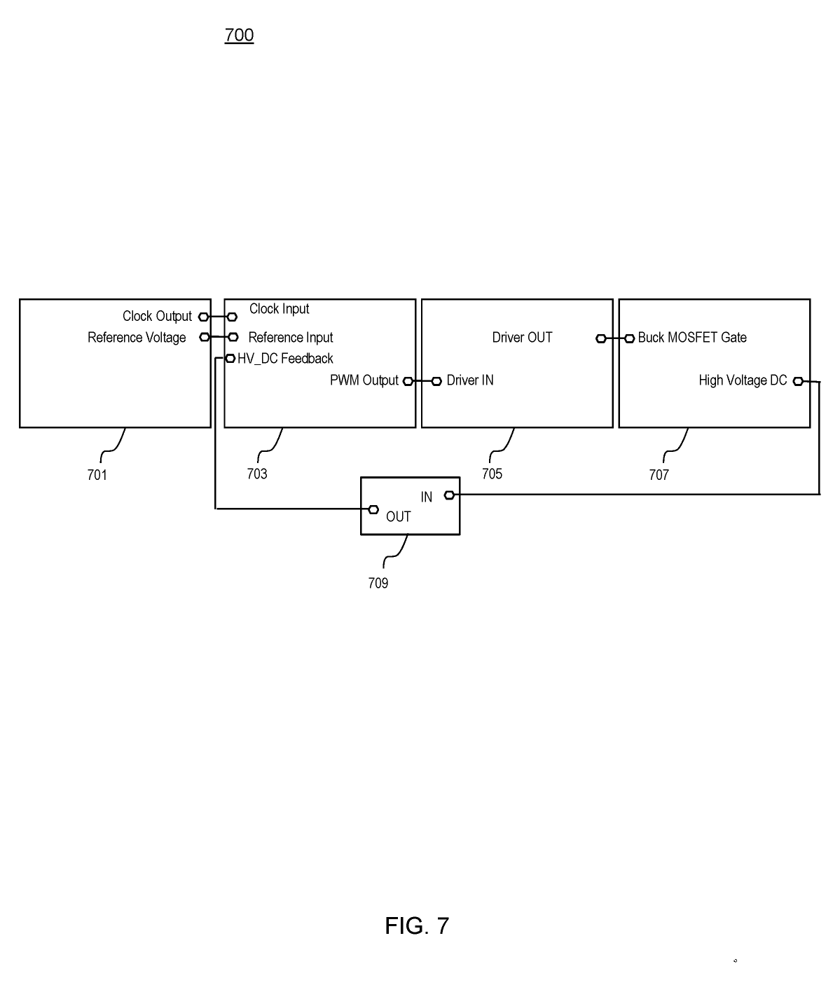

FIG. 7 illustrates an exemplary circuit for the buck regulator controller 421 shown in FIG. 4, according to an embodiment of the present invention. The exemplary circuit, as shown in FIG. 7, includes a digital controller 701, a pulse width modulator 703, a transistor gate driver 705, a variable DC power supply with buck transistor gate 707 and a voltage divider 709. This doubles up as a control circuit facilitating a voltage step-down and/or current step-up operation. Using a feedback loop, the circuit regulates the high voltage signal generated from the buck transistor with an appropriate voltage divider 709, which may be a resistor load. A pulse width modulator 703 modulates the high amplitude pulse to prevent unnecessary surges prevalent in high voltage applications. Accordingly, digital controller 701 provides a reference signal and a clock signal to pulse width modulator 703.

Embodiments of the present disclosure include a system having one or more processing units coupled to one or more memories. The one or more memories may be configured to store software that, when executed by the one or more processing unit, facilitates practice of embodiments described herein. For example, various controllers described herein, including digital controller 701, may include a respective processor coupled to a respective memory, the memory configured to store sets of program instructions that, when executed by the processor, carry out processes of the respective controller described herein.

Although the invention has been described with reference to exemplary embodiments, it is not limited thereto. Those skilled in the art will appreciate that numerous changes and modifications may be made to the preferred embodiments of the invention and that such changes and modifications may be made without departing from the true spirit of the invention. It is therefore intended that the appended claims be construed to cover all such equivalent variations as fall within the true spirit and scope of the invention.

The exemplary embodiments of this present invention have been described in relation to laboratory equipment. However, to avoid unnecessarily obscuring the present invention, the preceding description omits a number of known structures and devices. This omission is not to be construed as a limitation of the scope of the present invention. Specific details are set forth by use of the embodiments to provide an understanding of the present invention. It should however be appreciated that the present invention may be practiced in a variety of ways beyond the specific embodiments set forth herein.

A number of variations and modifications of the present invention may be used. It would be possible to provide for some features of the present invention without providing others.

The present invention, in various embodiments, configurations, and aspects, includes components, methods, processes, systems and/or apparatus substantially as depicted and described herein, including various embodiments, sub-combinations, and subsets thereof. Those of skill in the art will understand how to make and use the present invention after understanding the present disclosure. The present invention, in various embodiments, configurations, and aspects, includes providing devices and processes in the absence of items not depicted and/or described herein or in various embodiments, configurations, or aspects hereof, including in the absence of such items as may have been used in previous devices or processes, e.g., to improve performance, achieving ease and/or reducing cost of implementation.

The foregoing discussion of the present invention has been presented for purposes of illustration and description. It is not intended to limit the present invention to the form or forms disclosed herein. In the foregoing Detailed Description, for example, various features of the present invention are grouped together in one or more embodiments, configurations, or aspects for the purpose of streamlining the disclosure. The features of the embodiments, configurations, or aspects may be combined in alternate embodiments, configurations, or aspects other than those discussed above. This method of disclosure is not to be interpreted as reflecting an intention the present invention requires more features than are expressly recited in each claim. Rather, as the following claims reflect, inventive aspects lie in less than all features of a single foregoing disclosed embodiment, configuration, or aspect. Thus, the following claims are hereby incorporated into this Detailed Description, with each claim standing on its own as a separate embodiment of the present invention.

Moreover, though the description of the present invention has included description of one or more embodiments, configurations, or aspects and certain variations and modifications, other variations, combinations, and modifications are within the scope of the present invention, e.g., as may be within the skill and knowledge of those in the art, after understanding the present disclosure. It is intended to obtain rights which include alternative embodiments, configurations, or aspects to the extent permitted, including alternate, interchangeable and/or equivalent structures, functions, ranges or steps to those claimed, whether or not such alternate, interchangeable and/or equivalent structures, functions, ranges or steps are disclosed herein, and without intending to publicly dedicate any patentable subject matter.

What is claimed is:

1. A system to generate plasma to clean at least one object, the system comprising:
a microplate;
an electrode support array supporting the microplate, the electrode support array comprising a plurality of matched pairs of elongated dielectric barrier members connected to a plurality of electrodes, with said dielectric barrier members of said matched pair being spaced at a pre-determined non-uniform gap;
a variable time scale pulsed power source electrically coupled to the plurality of electrodes to provide a plurality of electrical pulses; and
a circuit to control polarity of the plurality of electrical pulses, wherein the plurality of electrical pulses produce a plurality of electron streamers from opposing elongated dielectric barrier members of said plurality of matched pairs, such that a charge on a surface of said dielectric barrier member is substantially evenly distributed.

2. The system of claim 1, wherein the variable time scale pulsed power source generates a pulsed direct current (DC) signal and a reversible pulsed DC signal.

3. The system of claim 1, wherein the variable time scale pulsed power source further comprises at least one of a circuit corresponding to a variable DC power supply, an analog to digital convertor, a bridging circuit, a plurality of transformers and a plurality of microprocessors.

4. The system of claim 3, wherein the bridging circuit further comprises control mechanisms to regulate a duty factor and a pulse width of a generated pulse.

5. The system of claim 1, wherein the system generates plasma at and near atmospheric pressure.

6. The system of claim 1, wherein said elongated dielectric barrier members are arranged on a planar surface.

7. The system of claim 1, wherein said elongated dielectric barrier members are spaced apart at substantially regular intervals to define predetermined uniform or non-uniform gaps.

8. The system of claim 7, wherein said pre-determined non-uniform gap comprises of a dielectric medium.

9. The system of claim 1, wherein said elongated dielectric barrier members are arranged to form a plurality of orderly rows.

10. The system of claim 1, wherein said elongated dielectric barrier members are arranged on a non-planar surface.

11. The system of claim 1, wherein shape of said elongated dielectric barrier members comprises one of tubular, circular, square, rectangular, oval, polygonal, triangular, trapezoidal, rhombus and irregular.

12. The system of claim 1, further comprising wires coupling said plurality of electrodes to said variable time scale pulsed power source.

13. The system of claim 1, further comprises a plurality of control circuits operating a programmable preloading of said variable time scale pulsed power source.

14. The system of claim 1, further comprises of a protection circuitry to detect one of an electric short circuit, an arc, and a leak.

15. An apparatus to generate plasma to clean at least one object with a variable time scale pulse power source to generate electrical pulses, wherein said power source comprising:
an input line connected to an alternating current (AC) line;
an output line coupled to and feeding said electrical pulses to a plurality of electrodes and a plurality of matched pairs of elongated dielectric barrier members corresponding to said electrodes;
a logic board with programmable modules; and
a power board comprising a rectifier, a buck regulator, an H-Bridge control circuit, a filter, a current sensing circuit and a circuit to control polarity of said electrical pulses, wherein the pulses produce plasma from opposing elongated dielectric barrier members of said plurality of matched pairs, such that charge on a surface of said dielectric barrier member is substantially evenly distributed.

16. The apparatus of claim 15, wherein said power source is preloaded with a pre-determined voltage.

17. The apparatus of claim 15, wherein said power source uses a closed loop control circuit to identify optimal periods to change polarity of an electrical pulse.

18. The apparatus of claim 15, wherein said power source further comprises a control circuit operating the programmable preloading of said variable time scale pulsed power source.

19. A system to generate plasma to clean at least one object, the system comprising:
a microplate with an electrode support array comprising a plurality of matched pairs of elongated dielectric barrier members connected to a plurality of electrodes, wherein said dielectric barrier members of said matched pair being spaced at a uniform or non-uniform gap and being arranged in a plurality of orderly rows;
a variable time scale pulsed power source electrically coupled to said electrodes to provide electrical pulses; and
a circuit to control polarity of said electrical pulses, wherein said electrical pulses produce plasma from opposing elongated dielectric barrier members of said plurality of matched pairs, such that charge on a surface of said dielectric barrier member is substantially evenly distributed.

20. The system of claim 19, wherein said variable time scale pulsed power source further comprises a programmable module.
